(19) United States
(12) Patent Application Publication
(10) Pub. No.: US 2025/0185219 A1
(43) Pub. Date: Jun. 5, 2025

(54) SERVER ROOM THERMO-HYGROSTAT USING OUTDOOR AIR

(71) Applicant: CHUNG LOCK OH, Gwangju (KR)

(72) Inventor: CHUNG LOCK OH, Gwangju (KR)

(21) Appl. No.: 18/527,234

(22) Filed: Dec. 1, 2023

(51) Int. Cl. H05K 7/20

(52) U.S. Cl. CPC H05K 7/20827; H05K 7/20154; H05K 7/20309; H05K 7/20318

(57) ABSTRACT

The present disclosure relates to a thermo-hygrostat that maintains the temperature and humidity in a server room at a certain level, and more specifically, to a server room thermo-hygrostat using outdoor air that is integrated with the indoor and outdoor units provided with a heat exchange element in which the server room can be cooled cleanly and power consumption can be reduced by using the outdoor air in winter, which has a lower temperature than the server room's set temperature.

### TECHNICAL FIELD

The present disclosure relates to a thermo-hygrostat that maintains the temperature and humidity in a server room at a certain level, and more specifically, to a server room thermo-hygrostat using outdoor air that is integrated with the indoor and outdoor units provided with a heat exchange element in which the server room can be cooled cleanly and power consumption can be reduced by using the outdoor air in winter, which has a lower temperature than the server room's set temperature.

### DISCUSSION OF RELATED ART

In general, air conditioning aims to maintain indoor conditions such as temperature, humidity, bacteria, odor, and airflow in a state suitable for the purpose of use of the location, thereby creating comfortable conditions for people living indoors in homes, hotels, halls, offices, computer rooms, and various industrial sites, etc. The air condition that is comfortable for people is affected by various conditions such as climatic conditions, clothing, standard of living, and health, so there is no fixed value. but it is usually aimed at a temperature of 26 to 28° C. and relative humidity of about 50% in summer, and a temperature of 20 to 22° C. and relative humidity of about 40% in winter.

However, these values are not absolute, and in order for places such as factory workshops, warehouses, laboratories, and computer rooms to fully fulfill their functions, they must be maintained in the most appropriate condition for the products produced, processed, stored, or tested there, or for the various devices operating in those places.

Air conditioning is used to prevent the quality of manufactured goods from being uneven or from producing many defective products. for example, in a tobacco factory, when chopping leaves, the humidity is relatively high to prevent them from drying out and turning into powder. in chocolate factories, the temperature is kept low to prevent the chocolate from melting and losing its shape, in the transistor manufacturing plant, dust is extremely reduced. and in the physiology laboratory, the air flow is slowed down to take into account the effect of wind on living organisms.

Among places that require thermo-hygrostat, data centers rent computer facilities and network facilities to companies and individuals or attract customers' facilities and provide services such as maintenance and repairs, and the server room of such a data center usually has a plurality of racks equipped with data servers and databases, including communication devices, installed in a row, and includes a workspace where workers can work.

For equipment including server racks, the temperature of the surrounding air rises due to the heat generated by the data servers. In this case, because equipment such as data servers do not operate smoothly in a high-temperature environment, a thermo-hygrostat that cools the air in the server room is needed. Further, in the case of parts or circuit equipment of various electronic devices installed in the server room, if humidity increases, there is a risk of electric leakage, and if humidity is too low, problems such as fire or damage to electronic components due to static electricity generation or sparks may occur.

To solve this problem, a conventional thermo-hygrostat cools and circulates the refluxing air using a refrigerant to a specified temperature and supplies it to maintain constant temperature and humidity in the server room.

In winter, even though the outdoor temperature is lower than the set temperature required for the server room, it is extremely cautious to directly cool the server room by drawing in outdoor air due to the nature of the server room, which must be maintained in a clean state. Therefore, the temperature in the server room was being cooled through the operation of the thermo-hygrostat.

As a result, a lot of power was consumed even in the winter, increasing energy costs and operating costs in the server room.

Therefore, there is a need to develop a thermo-hygrostat that can cool the server room using outdoor air in the winter and keep the server room clean by preventing the inflow of dust and foreign substances.

### SUMMARY

According In order to address the above issues, the present disclosure is to provide a thermo-hygrostat using the outdoor air, that is formed integrally without distinguishing between the indoor unit and the outdoor unit, in which in order to cool the server room without operating the evaporator and condenser in winter, when the temperature is lower than the server room's set temperature, a heat exchange element is provided as an integrated unit, and the indoor air of the server room is cooled by exchanging heat with the cold outdoor air in the heat exchange element, which reduces power consumption and improves the convenience of management and maintenance.

Further, the present disclosure is to provide a thermo-hygrostat using the outdoor air in which in the summer, when the outdoor air is at a higher temperature than the server room's set temperature, the damper is operated to absorb the heat emitted from the condenser without passing through the heat exchange element, and then discharged to the outdoors, and in winter, when the temperature is lower, through operation of the damper, outdoor air does not flow into the condensing unit and blowing unit, it passes only through the heat exchange element and is then discharged so that the outdoor air flow path can be variably controlled and the thermo-hygrostat can be operated efficiently depending on the outdoor temperature.

Further, the present disclosure is to provide a thermo-hygrostat using the outdoor air in which when operating the evaporator and condenser to cool the server room, the damper can be used to prevent hot outdoor air from flowing into the server room, thereby quickly cooling the air in the server room.

Further, the present disclosure is to provide a thermo-hygrostat using the outdoor air in which a flow path is formed so that indoor or outdoor air passes through the blowing unit to set the volume of the thermo-hygrostat to the minimum and to add flow force to both indoor and outdoor air even if a single second blowing fan is provided.

Further, the present disclosure is to provide a thermo-hygrostat using the outdoor air in which a partition separating the heat exchange element and the fifth damper and the sixth damper is provided in the second space in the spaces where the heat exchange unit is divided by the heat exchange element so that in summer mode, the outdoor air flowing by the second blowing fan does not re-enter the heat exchange element but is discharged outdoors through the sixth damper, and then outdoor air flows efficiently without unnecessary circulation.

The server room thermo-hygrostat using outdoor air includes an inlet unit 100 configured to have an indoor air inlet 110 through which indoor air flows and an evaporator 120 exchanging heat with the indoor air therein, an outlet unit 200 configured to be disposed on the upper part of the inlet unit 100, communicate with the inlet unit 100 through a first damper 210, have a first blowing fan 220 therein, and have an indoor air outlet 230 discharging cooled indoor air, a condensing unit 300 configured to be disposed on a side of the outlet unit 200, communicate with the outlet unit 200 through a ninth damper 240, and have a condenser 320 therein for heat exchange with outdoor air, a blowing unit 400 configured to be disposed on a side of the inlet unit 200 and a lower part of the condensing unit 300, communicate with the inlet unit 200 through a seventh damper 430, communicate with the condensing unit 300 through a fourth damper 410, and have a second blowing fan 420 therein, and a heat exchange unit 500 configured to be disposed on a side of the condensing unit 300 and the blowing unit 400, have a second damper 510 and a tenth damper 560 through which outdoor air flows, a sixth damper 530 and an eleventh damper 580 discharging outdoor air, and a heat exchange element 550 heat-exchanging between indoor and outdoor air wherein an internal space is partitioned through the heat exchange element 550, communicate with the condensing unit 300 through a third damper 310, and communicate with the blowing unit 400 through a fifth damper 520.

Further, the heat exchange unit 500 includes a first space 551 receiving outdoor air through the second damper 510 and discharging indoor or outdoor air into the condensing unit 300 through the third damper 310, a second space 552 receiving indoor or outdoor air through the fifth damper 520 and discharging outdoor air to outdoor through a sixth damper 530, a third space 553 receiving outdoor air through a tenth damper 560, which operates opposite to the opening and closing operation of the second damper 510, and a fourth space 554 having a third blowing fan 570 and discharging outdoor air to the outdoor through the eleventh damper 580.

Further, the server room thermo-hygrostat further includes a partition 540 configured to be disposed in the second space 552, disposed between the heat exchange element 550 and the fifth damper 520 and the sixth damper 530, and have an eighth damper 540.

Further, the operating mode of the thermo-hygrostat includes a summer mode in which the indoor air is cooled by passing through the evaporator 120 and a winter mode in which the indoor air is cooled by heat exchange with the outdoor air in the heat exchange element 550, and the second blowing fan 420 of the blowing unit 400 discharges outdoor air in the summer mode and discharge indoor air in the winter mode, and in the summer mode and winter mode, the inflow direction of indoor and outdoor air is different, but the discharge direction is the same.

Further, when the thermo-hygrostat operates in the summer mode, which cools the indoor air through heat exchange with the evaporator 120, the indoor air flowing into the indoor air inlet 110 is cooled as the indoor air passes through the evaporator 120, and the indoor air enters the outlet unit 200 through the open first damper 210 and is then discharged indoors through the indoor air outlet 230, and the outdoor air flowing into the first space 551 through the open second damper 510 enters the condensing unit 300 through the open third damper 310, then exchanges heat with the condenser 320, then enters the second space 552 via the blowing unit 400 through the opened fourth damper 410 and the fifth damper 520, and is then discharged outdoor through the open sixth damper 530 in the second space 552.

Further, when the thermo-hygrostat operates in the winter mode, which cools the indoor air through heat exchange with the outdoor air, the indoor air flowing into the indoor air inlet 110 enters the blowing unit 400 through the open seventh damper 430, enters then the second space 552 through the open fifth damper 520, is then cooled by outdoor air while passing through the heat exchange element 550, enters then the condensing unit 300 through the open third damper 310 in the first space 551, and is then discharged into indoor through the indoor air outlet 220 via the outlet unit 200 through the open ninth damper 240, and the outdoor air flowing into the third space 553 through the opened tenth damper 560 cools the indoor air while passing through the heat exchange element 550, and is then discharged to the outdoor through the open eleventh damper 580 in the fourth space 554.

Further, the outdoor air travels longer in the summer mode than in the winter mode, and the indoor air travels longer in the winter mode than in the summer mode.

Further, the second blowing fan 420 of the blowing unit 400 sucks in, in the summer mode, the outdoor air that has penetrated the heat exchange unit 500 from the condensing unit 300 and discharges the outdoor air back to the heat exchange unit 500. and sucks in, in the winter mode, the indoor air that has penetrated the inlet unit 100 and discharges the indoor air back to the heat exchange unit 500.

The present disclosure has an effect of providing a thermo-hygrostat using the outdoor air, that is formed integrally without distinguishing between the indoor unit and the outdoor unit, in which in order to cool the server room without operating the evaporator and condenser in winter, when the temperature is lower than the server room's set temperature, a heat exchange element is provided as an integrated unit, and the indoor air of the server room is cooled by exchanging heat with the cold outdoor air in the heat exchange element, which reduces power consumption and improves the convenience of management and maintenance.

Further, the present disclosure has an effect of providing a thermo-hygrostat using the outdoor air in which in the summer, when the outdoor air is at a higher temperature than the server room's set temperature, the damper is operated to absorb the heat emitted from the condenser without passing through the heat exchange element, and then discharged to the outdoors, and in winter, when the temperature is lower, through operation of the damper, outdoor air does not flow into the condensing unit and blowing unit, it passes only through the heat exchange element and is then discharged so that the outdoor air flow path can be variably controlled and the thermo-hygrostat can be operated efficiently depending on the outdoor temperature.

Further, the present disclosure has an effect of providing a thermo-hygrostat using the outdoor air in which when operating the evaporator and condenser to cool the server room, the damper can be used to prevent hot outdoor air from flowing into the server room, thereby quickly cooling the air in the server room.

Further, the present disclosure has an effect of providing a thermo-hygrostat using the outdoor air in which a flow path is formed so that indoor or outdoor air passes through the blowing unit to set the volume of the thermo-hygrostat to the minimum and to add flow force to both indoor and outdoor air even if a single second blowing fan is provided.

Further, the present disclosure has an effect of providing a thermo-hygrostat using the outdoor air in which a partition separating the heat exchange element and the fifth damper and the sixth damper is provided in the second space in the spaces where the heat exchange unit is divided by the heat exchange element so that in summer mode, the outdoor air flowing by the second blowing fan does not re-enter the heat exchange element but is discharged outdoors through the sixth damper, and then outdoor air flows efficiently without unnecessary circulation.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 illustrates a perspective view of a server room thermo-hygrostat using outdoor air according to the present disclosure;

FIG. 2 illustrates an exploded perspective view of a server room thermo-hygrostat using outdoor air according to the present disclosure;

FIG. 3 shows a cross-sectional view of a server room thermo-hygrostat using outdoor air according to the present disclosure;

FIG. 4 illustrates a perspective view showing the inlet unit and outlet unit in the server room thermo-hygrostat using outdoor air of the present disclosure;

FIG. 5 illustrates a perspective view showing the condensing unit and the blowing unit in the server room thermo-hygrostat using outdoor air of the present disclosure;

FIG. 6 illustrates (a) a perspective view and (b) a front view showing the heat exchanger in the server room thermo-hygrostat using outdoor air of the present disclosure;

FIG. 7 illustrates (a) an exploded perspective view and (b) a cross-sectional view showing the server room thermo-hygrostat using outdoor air of the present disclosure operating in summer mode; and

FIG. 8 illustrates (a) an exploded perspective view and (b) a cross-sectional view showing the server room thermo-hygrostat using outdoor air of the present disclosure operating in winter mode.

### DETAILED DESCRIPTION OF EXEMPLARY EMBODIMENTS

Hereinafter, a preferred embodiment of the present disclosure is described with reference to the accompanying drawings so that those skilled in the art can easily implement it.

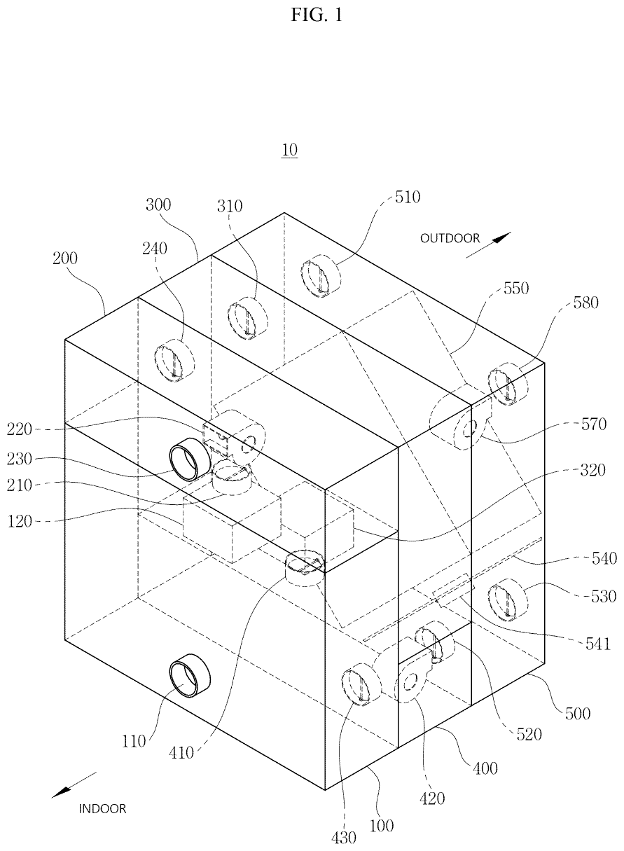

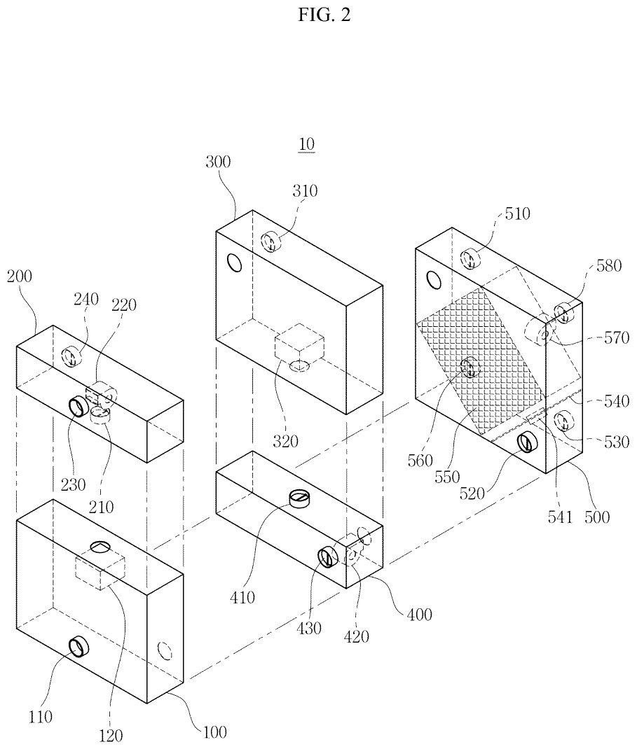

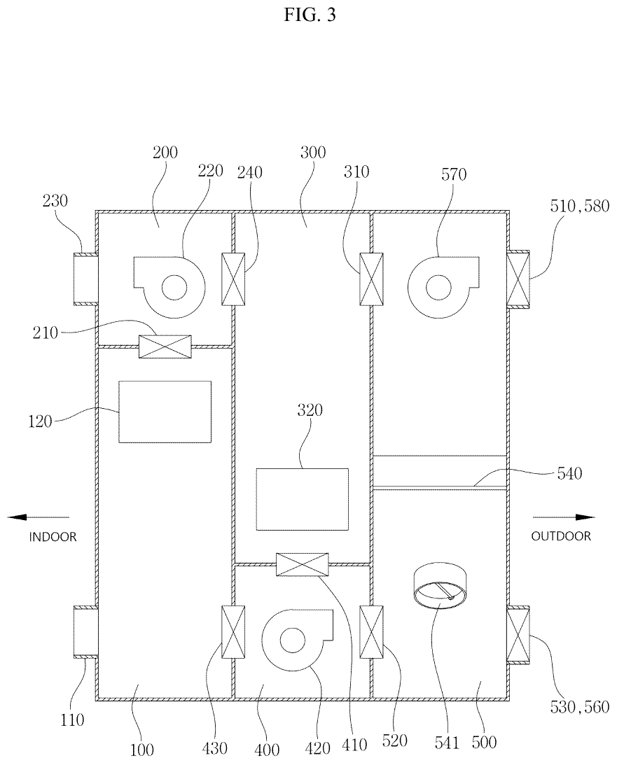

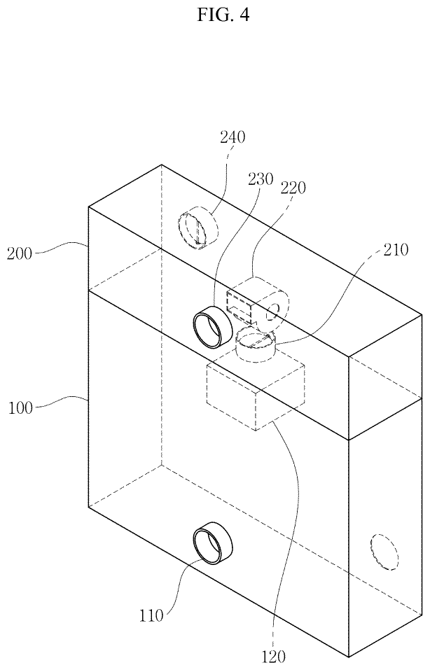

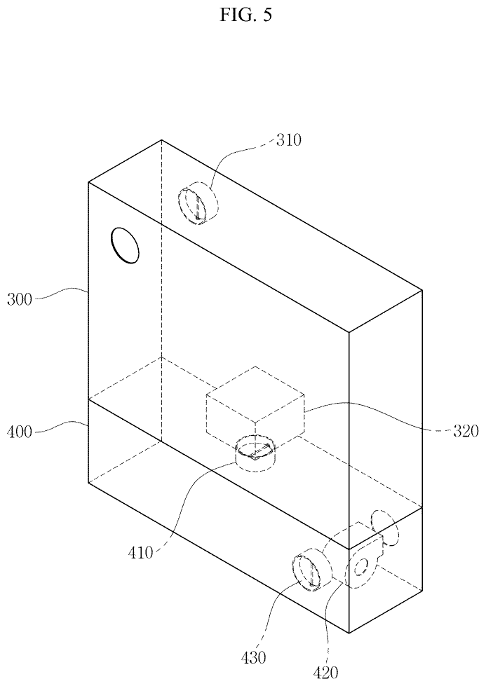

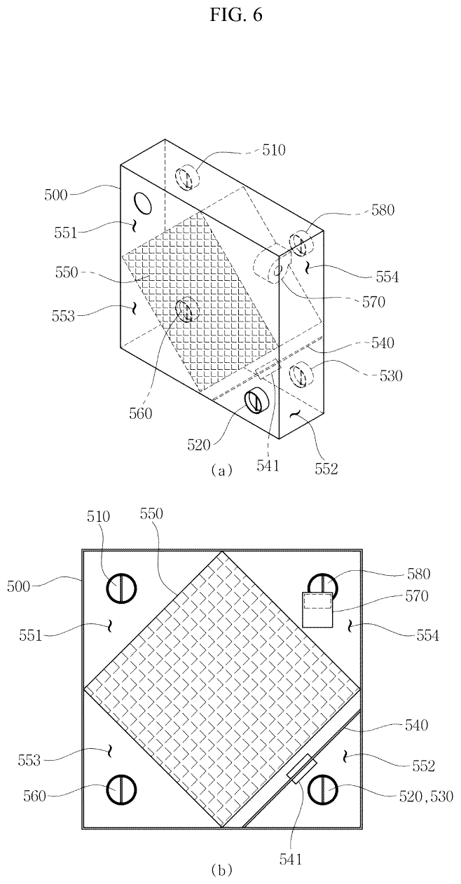

As shown in FIGS. 1 to 8, the server room thermo-hygrostat using outdoor air according to the present disclosure is provided to cool the air in a server room equipped with multiple heating equipment and is formed as an integrated unit without separating the indoor and outdoor units, and it is further equipped with a heat exchange element 550 to block polluted outdoor air from flowing into the server room. including the inlet unit 100 configured to have the indoor air inlet 110 through which indoor air flows and the evaporator 120 exchanging heat with the indoor air therein, the outlet unit 200 configured to be disposed on the inlet unit 100, communicate with the inlet unit 100 through the first damper 210, have the first blowing fan 220 therein, and have an indoor air outlet discharging cooled indoor air, the condensing unit 300 configured to be disposed on a side of the outlet unit 200, communicate with the outlet unit 200 through the ninth damper 240, and have the condenser 320 therein for heat exchange with outdoor air, the blowing unit 400 configured to be disposed on a side of the inlet unit 100 and below the condensing unit 300, communicate with the inlet unit 100 through the seventh damper 430, communicate with the condensing unit 300 through the fourth damper 410, and have the second blowing fan 420 therein, and the heat exchange unit 500 configured to be disposed on a side of the condensing unit 300 and the blowing unit 400, have the second damper 510 and the tenth damper 560 through which outdoor air flows, the sixth damper 530 and the eleventh damper 580 discharging outdoor air, and the heat exchange element 550 heat-exchanging between indoor and outdoor air wherein the internal space is partitioned through the heat exchange element 550, communicate with the condensing unit 300 through the third damper 310, and communicate with the blowing unit 400 through the fifth damper 520.

The server room is equipped with multiple racks equipped with heat-generating data servers and databases. The equipment in the server room must be operated at an appropriate temperature and humidity. If the temperature and humidity are inappropriate, the equipment may not operate smoothly or a fire may occur, so a thermo-hygrostat is installed to keep the air in the server room harmonious.

Typically, the thermo-hygrostat is divided into the indoor unit equipped with the evaporator 120 to exchange heat with the indoor air and the outdoor unit equipped with the condenser 320 to exchange heat with the outdoor air, and they are installed indoors and outdoors, respectively. However, the present disclosure provides an integrated thermo-hygrostat equipped with both the evaporator 120 and the condenser 320 inside the main body 10, so that the air heated in the server room is cooled by heat exchange with the refrigerant in the evaporator 120 and is then discharged into the server room to maintain the server room at a constant temperature.

However, when the outdoor air temperature is lower than the temperature at which the server room is set to a constant temperature state, such as in winter, rather than cooling the inside of the server room by exchanging heat with the refrigerant, cooling the inside of the server room by exchanging heat with the outdoor air has the advantage of reducing the power consumption required to circulate the refrigerant and saving energy. However, the server room must maintain clean air quality to prevent breakdowns in electronic equipment, so outdoor air cannot be accepted without filtering.

Therefore, in the present disclosure, in addition to a thermo-hygrostat equipped with both the evaporator 120 and the condenser 320 inside the main body 10, the heat exchange element 550 for heat exchange between indoor and outdoor air is provided in an integrated form. Therefore, even without operating the evaporator 120 and condenser 320, the indoor air is cooled by the cold outdoor air and supplied to the server room, thereby maintaining a constant temperature in the server room.

In the thermo-hygrostat according to the present disclosure, when the temperature of the outdoor air is higher than the temperature of the inside of the server room, the indoor and outdoor air do not exchange heat each other, but the indoor and outdoor air each exchange heat with the refrigerant circulating along the refrigeration cycle to cool the server room. However, when the temperature of the outdoor air is lower than the temperature of the inside of the server room, the indoor and outdoor air do not exchange heat with the refrigerant circulating through the refrigeration cycle, and the indoor and outdoor air exchange heat each other to cool the inside of the server room.

In order to achieve this, the thermo-hygrostat of the present disclosure, the indoor of one main body 10 is divided into a total of five spaces: an inlet unit 100, an outlet unit 200, a condensing unit 300, a blowing unit 400, and a heat exchange unit 500, and a plurality of dampers are provided to communicate with or block each partitioned space. By opening and closing each damper, the flow paths of indoor and outdoor air are variable inside the main body 10, and along the variable flow path, the indoor air and outdoor air exchange heat through a refrigerant, or the indoor air and outdoor air exchange heat with each other.

Therefore, the indoor unit, outdoor unit, and heat exchange element 550 are not provided in separate places but are housed inside one main body 10 to improve convenience of maintenance, and in winter, to cool the server room without operating the evaporator 120 and condenser 320, thereby dramatically reducing power consumption.

As shown in FIGS. 1, 7, and 8, in the present disclosure, the air inside the server room is referred to as indoor air, and the air outside the server room is referred to as outdoor air. In the thermo-hygrostat of the present disclosure, indoor air is not discharged to the outdoors, outdoor air is not introduced into the indoor room, and indoor air is circulated indoors. Therefore, it is possible to block dust and foreign substances contained in the outdoor air from entering the server room and protect the equipment within the server room.

However, the thermo-hygrostat according to the present disclosure is capable of introducing outdoor air into the room and can be controlled to discharge indoor air to the outdoors or allow outdoor air to flow into the room by opening and closing the damper.

In the present disclosure, the set temperature refers to the optimal temperature for smoothly operating electronic equipment in the server room.

Further, when explaining the operating mode of the thermo-hygrostat of the present disclosure, the mode in which the indoor air is cooled by the refrigeration cycle, which requires operation of the evaporator 120 and condenser 320 because the temperature of the outdoor air is higher than the set temperature, is referred to as summer mode, and the mode in which the indoor air is cooled by heat exchange between the indoor and outdoor air without operating the evaporator 120 and the condenser 320 the temperature of the outdoor air is lower than the set temperature, is referred to as winter mode.

However, the summer mode and winter mode are named after the characteristics of the season for convenience, and do not necessarily refer to modes that operate only in summer or winter. Even in spring and fall, the operating mode can be changed to summer mode or winter mode depending on the outdoor temperature. Changing the operation mode to summer mode or winter mode is determined by the set temperature of the server room and the temperature of the outdoor air.

The thermo-hygrostat according to the present disclosure is a device that cools the inside by operating a refrigeration cycle consisting of four cycles: evaporation>compression>condensation>expansion. In the inside of the single body 10, in order to cool the indoor air, it is provided with the evaporator 120 that exchanges heat with the indoor air, the condenser 320 that exchanges heat with the outdoor air to lower the temperature of the refrigerant, and the heat exchange element 550 that exchanges heat with the indoor and outdoor air. Here, other components such as the compressor and expansion valve that make up the refrigeration cycle are general, so their illustration and description are omitted. However, the refrigerant circulating in the refrigeration cycle moves along the interconnected evaporator 120 and condenser 320.

Referring to FIGS. 1 to 3, the internal space of the main body 10 is divided into the inlet unit 100, the outlet unit 200, the condensing unit 300, the blowing unit 400, and the heat exchange unit 500 according to its function. It is divided into five sections to form an independent internal space. Through the dampers, the inlet unit 100—the outlet unit 200, the inlet unit 100—the blowing unit 400, the blowing unit 400—the condensing unit 300, the blowing unit 400—the heat exchange unit 500, condensing unit 300—the outlet unit 200, and the condensing unit 300—the heat exchange unit 500 communicate with each other. The spaces listed above can be communicated or blocked by controlling the opening and closing of the damper.

Further, the thermo-hygrostat according to the present disclosure may be further equipped with a humidifier or dehumidifier to control the humidity of the inside. The location is preferably located in the inlet unit 100 or the outlet unit 200. However, in one embodiment of the present disclosure, illustration and detailed description of the humidifier or dehumidifier are excluded.

First, referring to FIGS. 1 to 4, the inlet unit 100 is a space that introduces the indoor air of the server room into the main body 10, and the indoor air inlet 110 for receiving the indoor air is formed at the lower part thereof. Further, the inlet unit 100 is provided with the evaporator 120 that cools the indoor air by exchanging heat with the refrigerant. The evaporator 120 is preferably located above the indoor air inlet 110. Only indoor air can flow into the inlet unit 100, and outdoor air does not flow into the inlet unit 100.

The inlet unit 100 communicates with the outlet unit 200 placed above it through the first damper 210, and communicates with the blowing unit 400 through the seventh damper 430.

Depending on the operation mode of the thermo-hygrostat in summer mode or winter mode, the indoor air flowing into the indoor air inlet 110 of the inlet unit 100 passes through the evaporator 120 or flows into another space without passing through the evaporator 120. More specifically, in the summer mode, the indoor air in the inlet unit 100 passes through the evaporator 120, exchanges heat with the refrigerant to be cooled, and flows out to the outlet unit 200 through the open first damper 210, and in winter mode, it does not pass through the evaporator 120 but exits to the blowing unit 400 through the seventh damper 430.

The first damper 210 and the seventh damper 430 have opposite opening and closing operations. That is, when the first damper 210 is opened, the seventh damper 430 is closed, but when the seventh damper 430 is opened, the first damper 210 is closed. The state in which the first damper 210 is open and the seventh damper 430 is closed is when the operation mode of the thermo-hygrostat is the summer mode, The state in which the seventh damper 430 is open and the first damper 210 is closed is when the operation mode of the thermo-hygrostat is winter mode.

In winter mode, preferably, in order for the indoor air flowing in through the indoor air inlet 110 to exit to the seventh damper 430 without obstruction, the evaporator 120 is disposed at a higher position than the indoor air inlet 110 and the seventh damper 430. In the winter mode, the indoor air does not pass through the evaporator 120, so in order to move smoothly, the evaporator 120 is placed at a height that does not impede the movement of the indoor air.

Referring to FIGS. 1 to 4, the outlet unit 200 is a space disposed above the inlet unit 100. Only air cooled by the evaporator 120 or by heat exchange with cold outdoor air can be introduced into the outlet unit 200, and the cooled air is discharged indoors to cool the server room.

The outlet unit 200 is formed with the indoor air inlet 230 that discharges the cold indoor air into the server room and is provided with the first blowing fan 220 for blowing the cold indoor air into the server room.

Further, the outlet unit 200 communicates with the inlet unit 200 through the first damper 210 and communicates with the condensing unit 400 through the nineth damper 240. The first damper 210 and the ninth damper 240 are controlled to open and close to form an air flow path, but the open and closed states of the first damper 210 and the ninth damper 240 are opposite to each other. For example, when the first damper 210 is opened, the ninth damper 240 is closed, and when the ninth damper 240 is opened, the first damper 210 is closed. The state in which the first damper 210 is open and the ninth damper 240 is closed is when the thermo-hygrostat operates in summer mode, and the state in which the first damper 210 is closed and the ninth damper 240 is open is when the thermo-hygrostat operates in winter mode.

Referring to FIGS. 1 to 3 and 5, the blowing unit 400 is disposed on the side of the inlet unit 100 and below the condensing unit 300, which will be described later, and communicates with the inlet unit 100 through the seventh damper 430 and communicates with the condensing unit 300 through the fourth damper 410. In addition, it communicates with the heat exchange unit 500 through the fifth damper 520, more specifically, it communicates with the second space 552 of the heat exchange unit 500 through the fifth damper 520, but does not communicate with the first space 551, third space 553, and fourth space 554, which are other spaces of the heat exchange unit 500.

The blowing unit 400 receives indoor air through the seventh damper 430 and outdoor air through the fourth damper 410. In this way, indoor or outdoor air can be introduced into the blowing unit 400, but indoor and outdoor air cannot stay at the same time.

In addition, the blowing unit 400 is provided with the second blowing fan 420, the indoor or outdoor air introduced inside is discharged to the heat exchange unit 500 by the flow force added by the second blowing fan 420. The indoor air flowing into the blowing unit 400 through the seventh damper 430 passes through the second blowing fan 420 and exits into the second space 552 of the heat exchanger 500 through the fifth damper 520, and the outdoor air flowing into the blowing unit 400 through the fourth damper 410 passes through the second blower fan 420 and exits into the second space 552 through the fifth damper 520.

The second blowing fan 420 may be provided alone and is arranged to discharge indoor or outdoor air toward the fifth damper 520. The opening and closing operations of the fourth damper 410 and the seventh damper 430 are opposite to each other. The fourth damper 410 is a damper that receives outdoor air into the blowing unit 400, and the seventh damper 430 is a damper that receives indoor air into the blowing unit 400. In summer mode, the fourth damper 410 is opened and the seventh damper 430 is closed, so that the blower 400 receives outdoor air and discharges the outdoor air into the second space 552 of the heat exchanger 500 through the second blowing fan 420, but in winter mode, the fourth damper 410 is closed and the seventh damper 430 is open, so that the blower 400 receives indoor air and discharges the indoor air into the second space 552 of the heat exchanger 500 through the second blowing fan 420. In this way, the second blowing fan 420 always discharges air into the second space 552 through the fifth damper 520, it is determined whether to discharge indoor air or outdoor air depending on the opening and closing operations of the fourth damper 410 and the seventh damper 430. In this way, the second blower fan 420 discharges outdoor air in summer mode or indoor air in winter mode. Indoor or outdoor air flows into the blowing unit 400 by the suction force of the second blowing fan 420, and the inflow directions of the indoor and outdoor air are the inlet unit 100 and the condensing unit 300, respectively, which are different from each other, but the discharge direction is the same as the second space 552 of the heat exchange unit 500.

Referring to FIGS. 1 to 3 and 5, the condensing unit 300 disposed on the blowing unit 400 and on the side of the outlet unit 200 communicates with the blowing unit 400 through the fourth damper 410 and communicates with the outlet unit 200 through the ninth damper 240. Further, it communicates with the heat exchange unit 500 through the third damper 310, and more specifically, communicates with the first space 551 of the heat exchange unit 500 through the third damper 310.

The condensing unit 300 receives indoor and outdoor air through the third damper 310. However, the indoor air flowing in through the third damper 310 exits the condensing unit 300 through the ninth damper 240, and the outdoor air exits the condensing unit 300 through the fourth damper 410. In this way, indoor or outdoor air can be introduced into the condensing unit 300, but indoor and outdoor air cannot stay at the same time.

The condenser 320 is disposed in the condensing unit 300 to lower the temperature of the refrigerant through heat exchange with outdoor air. Of the air flowing into the condenser 300, indoor air does not pass through the condenser 320, and only outdoor air passes through the condenser 320. Outdoor air flowing into the condenser 300 through the third damper 310 passes through the condenser 320 and exits into the blowing 400 through the fourth damper 410. On the other hand, the indoor air flowing into the condensing unit 300 through the third damper 310 does not pass through the condenser 320 but exits to the discharge unit 200 through the ninth damper 240.

In order for the indoor air flowing into the condensing unit 300 through the third damper 310 to be discharged through the ninth damper 240 without interfering with the flow, the condenser 320 is preferably placed lower than the third damper 310 and the ninth damper 240.

The third damper 310, fourth damper 410, and ninth damper 240 are each in communication with the condensing unit 300. The opening and closing operations of the fourth damper 410 and the ninth damper 240 are opposite to each other, and the third damper 310 is always open.

When the third damper 310 is opened, the ninth damper 240 is opened, and the fourth damper 410 is closed, the thermo-hygrostat operates in winter mode. In this case, the indoor air flows into the condensing unit 300 through the third damper 310 and exits from the condensing unit 300 through the ninth damper 240 without passing through the condenser 320.

When the third damper 310 is opened, the fourth damper 410 is opened, and the ninth damper 240 is closed, the thermo-hygrostat operates in summer mode. In this case, the outdoor air flows into the condensing unit 300 through the third damper 310 and exits from the condensing unit 300 through the fourth damper 410 after passing through the condenser 320.

Referring to FIGS. 1 to 3 and 6, the heat exchange unit 500 is disposed on the side of the condensing unit 300 and the blowing unit 400, and communicates with the condensing unit 300 through the third damper 310, communicates with the blowing unit 400 through the fifth damper 520, and equipped with the heat exchange element 550 that exchanges heat with the indoor air and the outdoor air. The internal space of the heat exchange unit 500 is partitioned by the heat exchange element 550 to include the first space 551 provided with the second damper 510, the second space 552 located opposite to the first space 551, the third space 553 provided with the tenth damper, and the fourth space 554 located opposite to the third space 553.

The second damper 510 in the first space 551 is a damper that introduces outdoor air into the heat exchange unit 500. Further, the first space 551 communicates with the condensing unit 300 through the third damper 310. The first space 551 is a space where outdoor air flows in from the outside through the second damper 510, and where indoor air passing through the heat exchange element 550 stays. In this way, the first space 551 is a space where indoor and outdoor air resides, but indoor and outdoor air cannot reside at the same time, and only one of them resides. The air remaining in the first space 551 is discharged to the condensing unit 300 through the third damper 310.

The second space 552 is a space where the fifth damper 520 and the sixth damper 530 are provided. It communicates with the blowing unit 400 through the fifth damper 520, and the indoor or outdoor air of the blowing unit 400 flows into the second space 552 through the fifth damper 520. Indoor and outdoor air, respectively, can flow into the second space 552, but only one can flow in at a time, and both indoor and outdoor air cannot flow in at the same time. Of air introduced through the fifth damper 520, the indoor air passes through the heat exchange element 550, and the outdoor air is discharged outdoors through the sixth damper 530 communicating with the outdoors.

Further, the partition 540 is provided in the second space 552. The partition 540 is a wall disposed between the heat exchange element 550 and the fifth damper 520 and the sixth damper 530 to separate them. The partition 540 is provided with the eighth damper 541, so that when the eighth damper 541 is opened, it can pass through the partition 540.

When the eighth damper 541 is closed, the thermo-hygrostat operates in summer mode. In this case, it is closed so that the outdoor air flowing in from the blowing unit 400 through the fifth damper 520 is blocked from passing through the heat exchange element 550 again, and the outdoor air is induced to be discharged outdoors through the sixth damper 530. The eighth damper 541 provided in the partition 540 is closed, so that outdoor air can flow efficiently without circulating unnecessarily inside the main body 10.

The third space 553 and fourth space 554 are spaces where only the outdoor air resides. The third space 553 is provided with the tenth damper 560 communicating with the outdoors, and the fourth space 554 is provided with the eleventh damper 580 communicating with the outdoors. Further, the third space 553 or the fourth space 554 is provided with the third blowing fan 570 that intakes outdoor air and adds flow force. The third blowing fan 570 according to an embodiment of the present disclosure is placed in the fourth space 554.

In winter mode, outdoor air flowing into the third space 553 through the tenth damper 560 passes through the heat exchange element 550 and moves to the fourth space 554 and then exits outdoors through the eleventh damper 580. The outdoor air passes through the heat exchange element 550 and exchanges heat with the indoor air to cool the indoor air.

There are two dampers through which outdoor air flows into the heat exchange unit 500, the second damper 510 and the tenth damper 560. However, it flows into the heat exchange unit 500 only through one of the second damper 510 and the tenth damper 560. More specifically, in summer mode, outdoor air flows into the first space 551 through the second damper 510, but in winter mode, outdoor air flows into the third space 553 through the tenth damper 560. The opening and closing operations of the second damper 510 and the tenth damper 560 are opposite to each other, and while one damper accepts outdoor air, the other damper is closed to block the inflow of outdoor air. That is, when the second damper 510 is opened, the tenth damper 560 is closed, but when the tenth damper 560 is opened, the second damper 510 is closed.

The eleventh damper 580 in the fourth space 554 is a damper that discharges outdoor air to the outdoors. The air flowing into the fourth space 554 is only the outdoor air in the third space 553 that has passed through the heat exchange element 550, and no air flows in from anywhere else.

In summer mode, the indoor and outdoor air do not pass through the heat exchange element 550 but move along the flow paths formed in each. Only in winter mode, mutual heat exchange occurs as indoor and outdoor air passes through the heat exchange element 550.

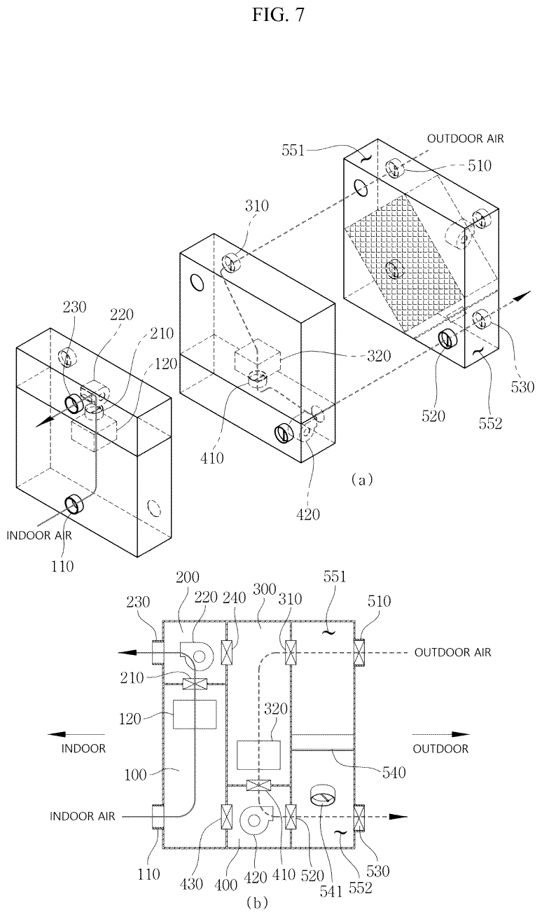

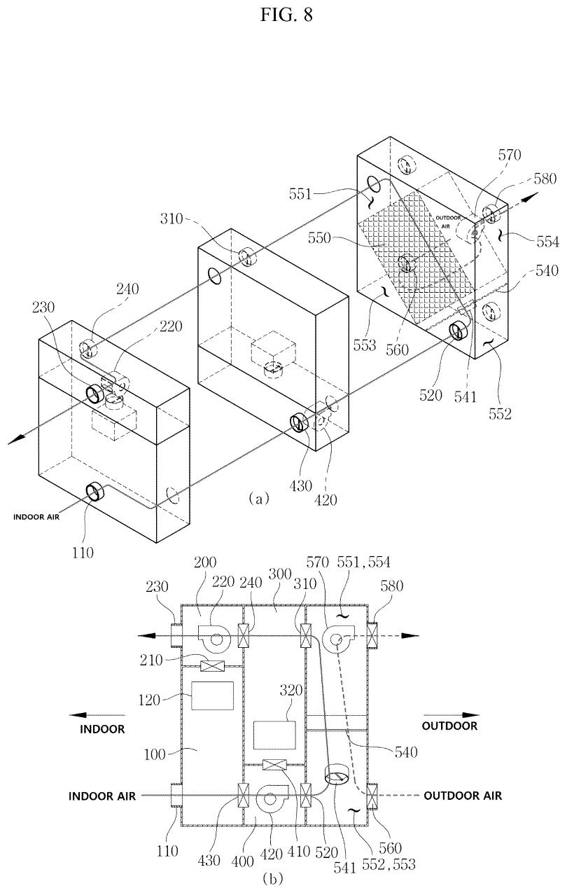

Hereinafter, with reference to FIGS. 7 and 8, the flow of indoor and outdoor is described in detail according to the operation mode of the server room thermo-hygrostat using outdoor air of the present disclosure.

Summer mode is a mode that operates the refrigeration cycle to cool the indoor air through heat exchange with the refrigerant when the temperature of the outdoor air is higher than the set temperature of the server room so that the indoor air cannot be cooled.

As shown in FIG. 7, referring to the flow path of indoor air when the thermo-hygrostat is operated in summer mode, indoor air in the server room flows into the inlet unit 100 through the indoor air inlet 110. At this time, the force for the indoor air to flow into the indoor air inlet 110 is generated by the suction force caused by the operation of the first blowing fan 220. Since the seventh damper 430 is closed, it does not move to the blowing unit 400, but passes through the evaporator 120 to be cooled by the refrigerant, and then flows into the outlet unit 200 through the opened first damper 210.

The cooled indoor air in the outlet unit 200 is discharged back into indoors the blowing force of the first blowing fan 220. At this time, preferably, the ninth damper 240 that communicates the outlet unit 200 and the condensing unit 300 is closed to prevent the outdoor air remaining in the condensing unit 300 from being discharged indoors by the first blowing fan 220.

Referring to the flow path of outdoor air in summer mode, outdoor air flows into the first space 551 through the open second damper 510 and enters the condensing unit 300 through the open third damper 310. At this time, the force for sucking the outdoor is generated by the suction force caused by the operation of the second blowing fan 420.

The outdoor air remaining in the condensing unit 300 does not flow into the discharge unit 200 by the closed ninth damper 240 but passes through the condenser 320 to be lowered the temperature of the refrigerant, and then enters the blowing unit 400 through the opened fourth damper 410.

The outdoor air sucked by the second blowing fan 420 in the blowing unit 400 is discharged and moves to the second space 552 of the heat exchanger 500 through the open fifth damper 520. Since the eighth damper 541 provided in the partition 540 is closed, the outdoor air remaining in the second space 552 does not pass through the heat exchange element 550 but is discharged outdoors through the open sixth damper 530.

As shown in FIG. 8, in winter mode, when the temperature of the outdoor air is lower than the set temperature of the server room to cool the indoor air, heat may be exchanged between the indoor air and the outdoor air to cool the indoor air without operating the refrigeration cycle including the evaporator 120 and the condenser 320, thereby saving energy.

Referring to the flow path of the indoor air in winter mode, the indoor air in the server room flows into the inlet unit 100 through the indoor air inlet 110. In winter mode, the force that causes the indoor air to flow through the indoor air inlet 110 is generated by the suction force caused by the operation of the first blowing fan 220 and the second blowing fan 420. In the summer mode, the air can be sucked in using only the first blowing fan 220, but in the winter mode, the first blowing fan 220 and the second blowing fan 420 are simultaneously used to generate a stronger suction force so that the indoor air can pass through the heat exchange element 550.

The indoor air in the inlet unit 100 enters the blowing unit 400 through the opened seventh damper 430. At this time, when the first damper 210 is opened, either the uncooled indoor air is discharged directly to the indoor air outlet 230, or the cooled indoor air is not completely discharged through the indoor air outlet 230, and enters the blowing unit 400 from the inlet unit 100 again by the suction force of the second blowing fan 420, so that the flow path becomes complicated and cooling efficiency decreases. Therefore, the first damper 210 is preferably closed.

The indoor air in the blowing unit 400 enters the second space 552 through the opened fifth damper 520. At this time, when the fourth damper 410 is opened, the indoor air cooled by passing through the heat exchange element 550 and then passing through the condenser 320 is drawn by the suction force of the second blower fan 420 to pass through the heat exchange element 550 again. To form an efficient flow path, the fourth damper 410 is preferably closed.

The eighth damper 541 provided on the partition 540 is open, so that the indoor air flowing into the second space 552 through the fifth damper 520 passes through the partition 540 through the eighth damper 541 and through the heat exchange element 550 to exchange heat with the outdoor air, thereby cooling the indoor air by the cold outdoor air and enters the first space 551. Further, it is not discharged to the outdoors by the second damper 510 closed in the first space 551 and enters the condensing unit 300 through the open third damper 310. Then, it enters the outlet unit 200 through the open ninth damper 240 by the suction power of the first blowing fan 220, and the cold indoor air is discharged indoors through the indoor air outlet 230.

Referring to the outdoor air flow path in winter mode, outdoor air flows into the third space 553 of the heat exchange unit 500 through the opened tenth damper 560. While passing through the heat exchange element 550 in the third space 553, heat is exchanged with the indoor air, thereby cooling the indoor air. And while exiting the heat exchange element 550, it stays in the fourth space 554 and is discharged outdoors through the open eleventh damper 580 by the third blowing fan 570. The third space 553 and the fourth space 554 communicate only outdoors and do not communicate with other spaces.

At this time, the outdoor air has a longer travel distance of the flow path in the summer mode than the winter mode, and the indoor air has a longer travel distance of the flow path in the winter mode than the summer mode.

Various changes in form or detail may be made to the present disclosure by one of ordinary skill in the art without departing from the scope of the present disclosure, and the present disclosure is not limited to the above-described embodiments and the accompanying drawings.

What is claimed is:

1. A server room thermo-hygrostat using outdoor air, the thermo-hygrostat comprising: an inlet unit configured to have an indoor air inlet through which indoor air flows and an evaporator exchanging heat with the indoor air therein;
an outlet unit configured to be disposed on the inlet unit, communicate with the inlet unit through a first damper, have a first blowing fan therein, and have an indoor air outlet discharging cooled indoor air;
a condensing unit configured to be disposed on a side of the outlet unit, communicate with the outlet unit through a ninth damper, and have a condenser therein for heat exchange with outdoor air;
a blowing unit configured to be disposed on a side of the inlet unit and below the condensing unit, communicate with the inlet unit through a seventh damper, communicate with the condensing unit through a fourth damper, and have a second blowing fan therein; and
a heat exchange unit configured to be disposed on a side of the condensing unit and the blowing unit, have a second damper and a tenth damper through which outdoor air flows, a sixth damper and an eleventh damper discharging outdoor air, and a heat exchange element heat-exchanging between indoor and outdoor air wherein an internal space is partitioned through the heat exchange element, communicate with the condensing unit through a third damper, and communicate with the blowing unit through a fifth damper.

2. The server room thermo-hygrostat of claim 1, wherein the heat exchange unit comprises:
a first space receiving outdoor air through the second damper and discharging indoor or outdoor air into the condensing unit through the third damper;
a second space receiving indoor or outdoor air through the fifth damper and discharging outdoor air to outdoor through a sixth damper;
a third space receiving outdoor air through a tenth damper, which operates opposite to the opening and closing operation of the second damper; and
a fourth space having a third blowing fan and discharging outdoor air to the outdoor through the eleventh damper.

3. The server room thermo-hygrostat of claim 2, further comprising:
a partition configured to be disposed in the second space, disposed between the heat exchange element and the fifth damper and the sixth damper, and have an eighth damper.

4. The server room thermo-hygrostat of claim 1,
wherein an operating mode of the thermo-hygrostat includes a summer mode in which the indoor air is cooled by passing through the evaporator and a winter mode in which the indoor air is cooled by heat exchange with the outdoor air in the heat exchange element; and
wherein the second blowing fan of the blowing unit discharges outdoor air in the summer mode and discharge indoor air in the winter mode, and in the summer mode and winter mode, the inflow direction of indoor and outdoor air is different, but the discharge direction is the same.

5. The server room thermo-hygrostat of claim 2,
wherein when the thermo-hygrostat operates in the summer mode, which cools the indoor air through heat exchange with the evaporator,
the indoor air flowing into the indoor air inlet is cooled as the indoor air passes through the evaporator, and the indoor air enters the outlet unit through the open first damper and is then discharged indoors through the indoor air outlet; and
the outdoor air flowing into the first space through the open second damper enters the condensing unit through the open third damper, then exchanges heat with the condenser, then enters the second space via the blowing unit through the opened fourth damper and the fifth damper and is then discharged outdoor through the open sixth damper in the second space.

6. The server room thermo-hygrostat of claim 2, wherein when the thermo-hygrostat operates in the winter mode, which cools the indoor air through heat exchange with the outdoor air,
the indoor air flowing into the indoor air inlet enters the blowing unit through the open seventh damper, enters then the second space through the open fifth damper, is then cooled by outdoor air while passing through the heat exchange element, enters then the condensing unit through the open third damper in the first space, and is then discharged into indoor through the indoor air outlet via outlet unit through the open ninth damper; and
the outdoor air flowing into the third space through the opened tenth damper 560 cools the indoor air while passing through the heat exchange element and is then discharged to the outdoor through the open eleventh damper in the fourth space.

7. The server room thermo-hygrostat of claim 4, wherein the outdoor air travels longer in the summer mode than in the winter mode, and the indoor air travels longer in the winter mode than in the summer mode.

8. The server room thermo-hygrostat of claim 4, wherein the second blowing fan of the blowing unit sucks in, in the summer mode, the outdoor air that has penetrated the heat exchange unit from the condensing unit and discharges the outdoor air back to the heat exchange unit and sucks in, in the winter mode, the indoor air that has penetrated the inlet unit and discharges the indoor air back to the heat exchange unit.
